(19) United States
(12) Patent Application Publication
(10) Pub. No.: US 2009/0001438 A1
(43) Pub. Date: Jan. 1, 2009

(54) Isolation of MIM FIN DRAM capacitor

(76) Inventors: Brian S. Doyle, Portland, OR (US); Dinesh Somasekhar, Portland, OR (US); Robert S. Chau, Beaverton, OR (US); Suman Datta, Port Matilda, PA (US)

Correspondence Address: CAVEN & AGHEVLI;c/o INTELLEVATE, LLC, P.O. BOX 52050, MINNEAPOLIS, MN, 55402, US

(21) Appl. No.: 11/824,499

(22) Filed: Jun. 29, 2007

(51) Int. Cl. H01L 29/94; H01L 21/20

(52) U.S. Cl. 257/306; 438/396; 257/E21.09; 257/E29.345

(57) ABSTRACT

In one embodiment, a capacitor comprises a substrate, a first electrically insulating layer over the substrate, a fin comprising a semiconducting material over the first electrically insulating layer, a cap formed from a silicide material on the first semiconducting fin, a first electrically conducting layer over the first electrically insulating layer and adjacent to the fin, a second electrically insulating layer adjacent to the first electrically conducting layer and a second electrically conducting layer adjacent to the second electrically insulating layer.

### BACKGROUND

The disclosed embodiments of the invention relate generally to capacitors, and relate more particularly to fin capacitors capable of use in embedded memory applications.

Today's computer chips are increasingly dependent on robust memory architecture capable of quickly accessing and handling large amounts of data. Existing memory solutions such as off-chip physical dynamic random access memory (DRAM) that sit on the mother board separate from the computer chip require relatively large amounts of energy and suffer from high latency, resulting in power-performance loss. Latency problems have been addressed using 1T-1C DRAM cells embedded on the computer chip, but existing versions of such DRAM cells are frequently unable to meet ever-increasing capacitance demands. Accordingly, there exists a need for a large-size, high-density capacitor compatible with a 1T-1C embedded DRAM cell usable within a logic technology process.

### BRIEF DESCRIPTION OF THE DRAWINGS

The disclosed embodiments will be better understood from a reading of the following detailed description, taken in conjunction with the accompanying Figures in the drawings in which:

FIG. 1 is a cross-sectional view of a capacitor according to an embodiment of the invention.

FIG. 2 is a cross-sectional view of a tri-gate memory cell at a particular point in its manufacturing process according to an embodiment of the invention;

FIG. 3 is a flowchart illustrating a method of isolating a MIM FIN DRAM capacitor, according to an embodiment of the invention;

FIGS. 4A-4C are cross-sectional views of the capacitor of FIG. 1 at different points in its manufacturing process according to embodiments of the invention;

FIG. 5 is a schematic representation of a system including a capacitor according to an embodiment of the invention.

For simplicity and clarity of illustration, the drawing Figures illustrate the general manner of construction, and descriptions and details of well-known features and techniques may be omitted to avoid unnecessarily obscuring the discussion of the described embodiments of the invention. Additionally, elements in the drawing Figures are not necessarily drawn to scale. For example, the dimensions of some of the elements in the Figures may be exaggerated relative to other elements to help improve understanding of embodiments of the present invention. The same reference numerals in different Figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used.

### DETAILED DESCRIPTION OF THE DRAWINGS

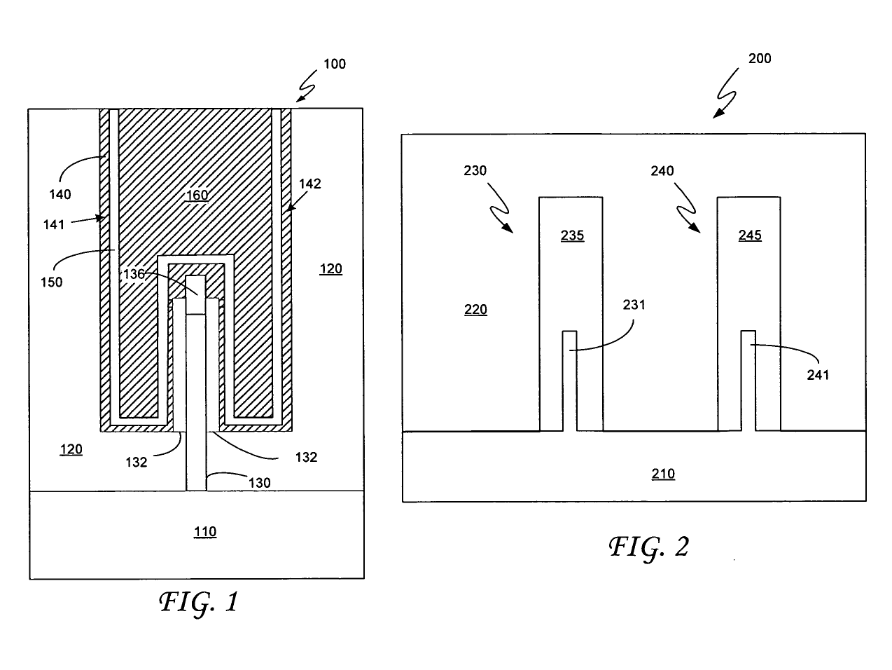

Referring now to the Figures, FIG. 1 is a cross-sectional view of a capacitor 100 according to an embodiment. As illustrated in FIG. 1, capacitor 100 comprises a substrate 110, an electrically insulating layer 120 over substrate 110, and a fin 130 comprising a semiconducting material over electrically insulating layer 120. As an example, electrically insulating layer 120 can be an oxide slab. As another example, fin 130 may be formed from a semiconducting material such as silicon (Si), germanium (Ge), silicon germanium (SiGe), a III-V material such as gallium arsenide (GaAs), or the like. In some embodiments the semiconductor substrate 110 and the fin 130 are doped P+.

Capacitor 100 further comprises an electrically conducting layer 140 over electrically insulating layer 120, an electrically insulating layer 150 adjacent to electrically conducting layer 140, and an electrically conducting layer 160 adjacent to electrically insulating layer 150. In some embodiments, capacitor 100 may be a decoupling capacitor. In some embodiments, capacitor 100 comprises a tri-gate storage capacitor, with the three gates located at the three interfaces between a face of fin 130 and an adjacent portion of electrically conducting layer 140 that may be used along with a tri-gate transistor as part of a 1T-1C DRAM cell.

In one embodiment, electrically insulating layer 150 comprises a high-k dielectric material such as hafnium oxide (HfO₂), zirconium oxide (ZrO₂), lanthanum oxide (LnO₂), or the like, including combinations and/or laminates thereof, each of which have dielectric constants of approximately 20 to approximately 40. Compare this to silicon dioxide which was for many years widely used as a gate dielectric material and which has a dielectric constant (κ) of approximately 3.9. (Although the dielectric constant is often represented by the Greek letter κ, it is usually the lower case Roman letter “k” that is used in such phrases as “high-k dielectric material,” and that convention will be followed here.) The dielectric constant of a vacuum, which is used as a scale reference point, is defined as 1. Accordingly, any material having a dielectric constant greater than about 5 or 10 would likely properly be considered a high-k material.

In one embodiment, electrically insulating layer 120 comprises an electrically insulating material, and in the same or another embodiment, electrically conducting layer 140 comprises an electrically conducting material. (In another embodiment electrically conducting layer 140 can comprise a semiconducting material.) In one embodiment, as mentioned above, the electrically insulating material of electrically insulating layer 120 is an oxide material. In the same or another embodiment, the electrically conducting material of electrically conducting layer 140 can be a metal having a work function that lies approximately mid-way between a conductive band and a valence band of the oxide or other electrically insulating material of electrically insulating layer 120. A material having a work function as described may be used to control leakage. As an example, the metal can be titanium nitride (TiN), tantalum nitride (TaN), or the like.

In one embodiment, electrically conducting layer 160 comprises an electrically conducting material that is the same as the electrically conducting material making up electrically conducting layer 140. In a different embodiment, however, electrically conducting layer 160 comprises an electrically conducting material that is different from the electrically conducting material making up electrically conducting layer 140. Using different electrically conducting materials may be desirable when, to take one example, processing issues dictate that one of the electrically conducting materials be more etchable than the other electrically conducting material.

In the embodiment depicted in FIG. 1, fin 130 is coated with a layer of insulating material 132. Fin 130 further comprises a silicide cap 136 formed on the upper surface of fin 130. In the embodiment depicted in FIG. 1, the insulating material covers the entire fin 130 and a portion of cap 136. Thus, fin 130 is insulted from electrically conductive material 140, which at least a portion of cap 136 is exposed to electrically conductive material 140. In alternate embodiments, the entire cap 136 may be exposed to electrically conductive material.

FIG. 2 is a cross-sectional view of a tri-gate memory cell 200 at a particular point in its manufacturing process according to an embodiment of the invention. As illustrated in FIG. 2, tri-gate memory cell 200 comprises a substrate 210, an electrically insulating layer 220 over substrate 210, and a tri-gate capacitor 230 and a tri-gate transistor 240, which may be either an access or a logic transistor, over electrically insulating layer 220. Tri-gate capacitor 230 has a semiconducting fin 231. As an example, substrate 210, electrically insulating layer 220, and semiconducting fin 231 can be similar to, respectively, substrate 110, electrically insulating layer 120, and fin 130, all of which are shown in FIG. 1. Tri-gate transistor 240 has a semiconducting fin 241 which may be similar to semiconducting fin 231. A polysilicon region 235 at least partially surrounds tri-gate capacitor 230, and a polysilicon region 245 at least partially surrounds tri-gate transistor 240. Tri-gate capacitor 230 and tri-gate transistor 240 are at least partially surrounded by an ILD 270. As an example, ILD 270 can be similar to ILD 170, shown in FIG. 1.

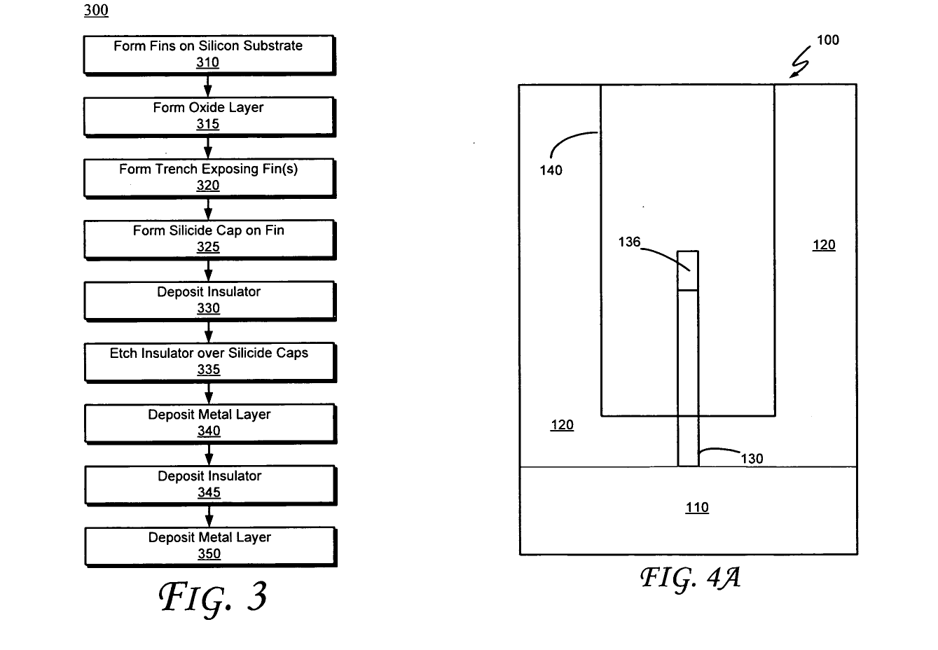

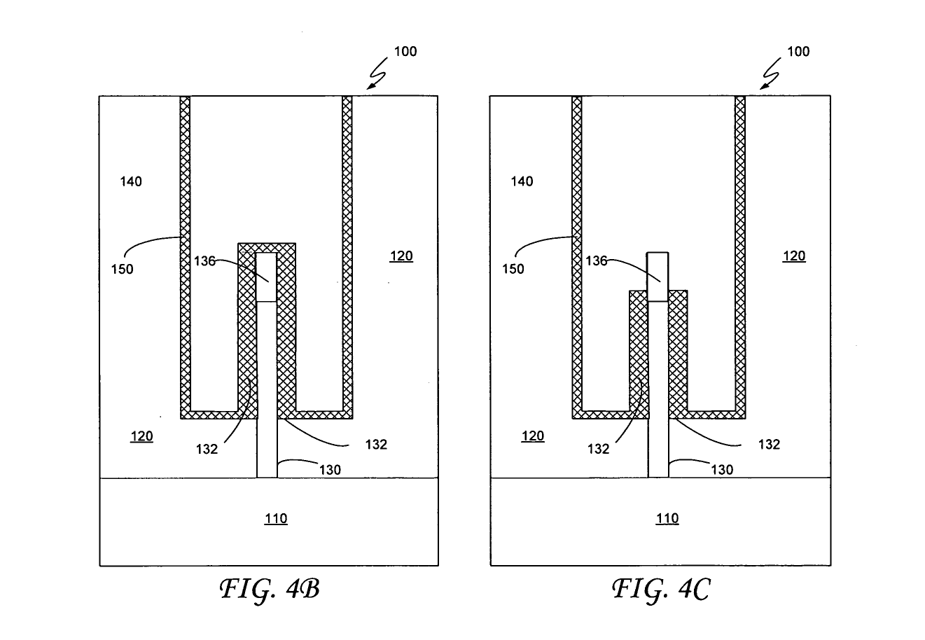

One technique for forming the capacitor depicted in FIG. 1 will be described with reference to FIG. 3 and FIGS. 4A-4C. FIG. 3 is a flowchart illustrating a method of isolating a MIM FIN DRAM capacitor, according to an embodiment of the invention, and FIGS. 4A-4C are cross-sectional views of the capacitor of FIG. 1 at different points in its manufacturing process according to embodiments of the invention.

At operation 310 one or more fins 130 are formed on a substrate 110. At operation 315 an oxide layer 120 is formed on the substrate 120, and at operation 320 a trench is formed in the oxide layer, exposing the fin(s) on the substrate 110. At operation 325 a silicide cap 136 is formed on the fin 130. In some embodiments the silicide cap 136 may be formed by removing a portion of the oxide layer 120, then applying a silicide compound on the fin 130. The oxide layer may then be regrown with one or more additional layers. The result is the structure depicted in FIG. 4A.

At operation 330 a layer of insulating material 132 is deposited in the trench such that it covers the fin 130 and the silicide cap 136. In some embodiments, the insulating material 132 may be formed from can be a layer of nitride, oxide, or the like, which may be deposited by a suitable deposition process such as, e.g., a chemical vapor depositon (CVD) process, an atomic layer deposition (ALD), or the like. The resulting structure is depicted in FIG. 4B.

At operation 335 the layer of insulating material 132 surrounding at least a portion of the silicide cap is removed. In some embodiments the layer may be removed by an etching process, which may be either a dry etch process or a wet etch process. The resulting structure is depicted in FIG. 4C.

Operations 340-350 fill the trench with metal-insulator-metal (MIM) layers to form the MIM capacitor depicted in FIG. 1. At operation 340 a first metal layer 140 is deposited in the trench of the structure depicted in FIG. 4C. At operation 345 a insulating layer 150 is deposited over the first metal layer, and at operation 350 a second metal layer 160 is deposited over the insulating layer 150. Thus, as depicted in FIG. 1, the fin 130 remains electrically isolated from the first conducting layer 140, while a portion of the cap 136 is in electrical communication with the first metal layer 140.

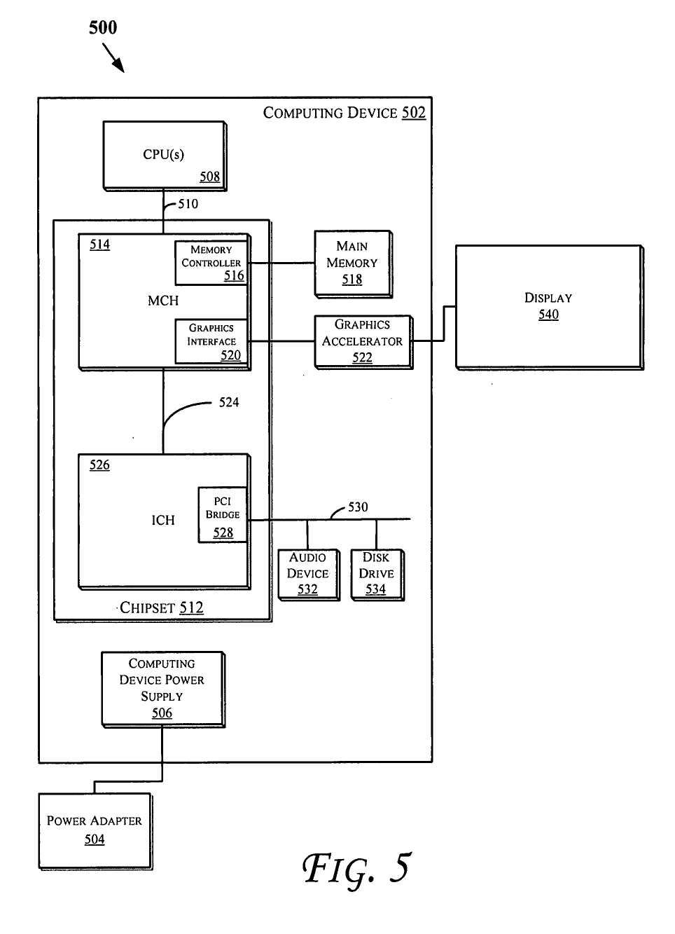

FIG. 5 is a schematic illustration of a computer system 500 in accordance with an embodiment. The computer system 500 includes a computing device 502 and a power adapter 504 (e.g., to supply electrical power to the computing device 502). The computing device 502 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 502 (e.g., through a computing device power supply 506) from one or more of the following sources: one or more battery packs, an alternating current (AC) outlet (e.g., through a transformer and/or adaptor such as a power adapter 504), automotive power supplies, airplane power supplies, and the like. In one embodiment, the power adapter 504 may transform the power supply source output (e.g., the AC outlet voltage of about 110VAC to 240VAC) to a direct current (DC) voltage ranging between about 7VDC to 12.6VDC. Accordingly, the power adapter 504 may be an AC/DC adapter.

The computing device 502 may also include one or more central processing unit(s) (CPUs) 508 coupled to a bus 510. In one embodiment, the CPU 508 may be one or more processors in the Pentium® family of processors including the Pentium® II processor family, Pentium® III processors, Pentium® IV processors available from Intel® Corporation of Santa Clara, Calif. Alternatively, other CPUs may be used, such as Intel's Itanium®, XEON™, and Celeron® processors. Also, one or more processors from other manufactures may be utilized. Moreover, the processors may have a single or multi core design.

A chipset 512 may be coupled to the bus 510. The chipset 512 may include a memory control hub (MCH) 514. The MCH 514 may include a memory controller 516 that is coupled to a main system memory 518. The main system memory 518 stores data and sequences of instructions that are executed by the CPU 508, or any other device included in the system 500. In one embodiment, the main system memory 518 includes random access memory (RAM); however, the main system memory 518 may be implemented using other memory types such as dynamic RAM (DRAM), synchronous DRAM (SDRAM), and the like. Additional devices may also be coupled to the bus 510, such as multiple CPUs and/or multiple system memories.

The MCH 514 may also include a graphics interface 520 coupled to a graphics accelerator 522. In one embodiment, the graphics interface 520 is coupled to the graphics accelerator 522 via an accelerated graphics port (AGP). In an embodiment, a display (such as a flat panel display) 540 may be coupled to the graphics interface 520 through, for example, a signal converter that translates a digital representation of an image stored in a storage device such as video memory or system memory into display signals that are interpreted and displayed by the display. The display 540 signals produced by the display device may pass through various control devices before being interpreted by and subsequently displayed on the display.

A hub interface 524 couples the MCH 514 to an input/output control hub (ICH) 526. The ICH 526 provides an interface to input/output (I/O) devices coupled to the computer system 500. The ICH 526 may be coupled to a peripheral component interconnect (PCI) bus. Hence, the ICH 526 includes a PCI bridge 528 that provides an interface to a PCI bus 530. The PCI bridge 528 provides a data path between the CPU 508 and peripheral devices. Additionally, other types of I/O interconnect topologies may be utilized such as the PCI Express™ architecture, available through Intel® Corporation of Santa Clara, Calif.

The PCI bus 530 may be coupled to an audio device 532 and one or more disk drive(s) 534. Other devices may be coupled to the PCI bus 530. In addition, the CPU 508 and the MCH 514 may be combined to form a single chip. Furthermore, the graphics accelerator 522 may be included within the MCH 514 in other embodiments.

Additionally, other peripherals coupled to the ICH 526 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 502 may include volatile and/or nonvolatile memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A method of forming a capacitor having a first semiconducting fin, the method comprising:
forming a cap from a silicide material on the first semiconducting fin;
depositing an electrically insulating layer over the first semiconducting fin and the cap;
removing a portion of the electrically insulating layer from the cap;
depositing a first metal layer over the electrically insulating layer and over the cap;
depositing a second electrically insulating layer over the first metal layer; and
depositing a second metal layer over the second electrically insulating layer.

2. The method of claim 1, wherein forming a cap from a conductive material on the first semiconducting fin further comprises:
exposing a portion of the first semiconducting fin; and
applying a silicide layer to the exposed portion of the fin.

3. The method of claim 1, wherein depositing an electrically insulating layer over the first semiconducting fin and the cap comprises depositing a nitride layer.

4. The method of claim 3, wherein removing a portion of the electrically insulating layer from the cap comprises etching a portion of the nitride layer.

5. The method of claim 1, wherein depositing a second electrically insulating layer over the first metal layer comprises depositing a high-k dielectric material.

6. The method of claim 1 wherein depositing a second metal layer over the second electrically insulating layer comprises depositing a layer comprising the first metal.

7. A capacitor comprising:
a substrate;
a first electrically insulating layer over the substrate;
a fin comprising a semiconducting material over the first electrically insulating layer;
a cap formed from a silicide material on the first semiconducting fin;
a first electrically conducting layer over the first electrically insulating layer and adjacent to the fin;
a second electrically insulating layer adjacent to the first electrically conducting layer; and
a second electrically conducting layer adjacent to the second electrically insulating layer.

8. The capacitor of claim 7 wherein:
the first electrically insulating layer comprises an oxide layer;
the fin comprises silicon compound; and
the second electrically insulating layer comprises a high-k dielectric material.

9. The capacitor of claim 7 wherein:
the first electrically insulating layer comprises a first electrically insulating material;
the first electrically conducting layer comprises a first electrically conducting material; and
the first electrically conducting material comprises a metal having a work function that lies approximately mid-way between a conductive band and a valence band of the first electrically insulating material.

10. The capacitor of claim 7 wherein the second electrically conducting layer comprises the first electrically conducting material.

11. The capacitor of claim 7, wherein the substrate and the fin are p-doped.

12. The capacitor of claim 7, wherein the cap is n-doped.

13. The capacitor of claim 7, wherein the fin in is substantially totally insulated except for the silicided portion.
